(19) United States
(12) Patent Application Publication
(10) Pub. No.: US 2018/0086044 A1
(43) Pub. Date: Mar. 29, 2018

(54) APPARATUS AND METHOD FOR SEPARATING POLYSILICON-CARBON CHUCK

(71) Applicant: OCI COMPANY LTD., Seoul (KR)

(72) Inventors: Byung Hyun PARK, Seongnam-si (KR); Ga Bok KIM, Seongnam-si (KR); Chang Won JEONG, Seongnam-si (KR); Byung Chang KANG, Seongnam-si (KR)

(21) Appl. No.: 15/702,259

(22) Filed: Sep. 12, 2017

(30) Foreign Application Priority Data
Sep. 23, 2016 (KR) 10-2016-0121861

(51) Int. Cl. B32B 43/00; C30B 25/12

(52) U.S. Cl. CPC B32B 43/006; C30B 29/06; C30B 25/12

(57) ABSTRACT

Disclosed herein are an apparatus and a method for separating polysilicon from a carbon chuck. The apparatus carries out induction-heating by applying a high-frequency current on a carbon chuck with polysilicon adhering thereto (a polysilicon-carbon chuck) retrieved from a chamber for synthesizing polysilicon, to thereby selectively heat the carbon chuck. Therefore, it is possible to melt the contact surface of the polysilicon in contact with the carbon chuck, and to separate and collect both the polysilicon and the carbon chuck without damaging them

### CROSS-REFERENCE TO RELATED APPLICATIONS

This application claims the priority of Korean Patent Application No. 10-2016-0121861 filed on Sep. 23, 2016, in the Korean Intellectual Property Office, the disclosure of which is hereby incorporated by reference in its entirety.

### BACKGROUND

### 1. Technical Field

The present disclosure relates to an apparatus and a method for separating polysilicon from a carbon chuck, and more particularly, to an apparatus and a method for separating and collecting polysilicon adhering to a carbon chuck retrieved from a chamber for synthesizing polysilicon without damaging them.

### 2. Description of the Related Art

Poly-silicon is a raw material used to make semiconductor wafers and solar cell panels and is a next-generation high-tech material that is attracting attention as the potential of the solar cell industry grows up remarkably.

The Siemens process is commonly used for producing polysilicon. According to this process, slim rods are placed in a bell-jar reactor, the slim rods are electrically heated by electrodes, and then trichlorosilane or monosilane (SiH₄) is injected along with hydrogen (H2) gas to pyrolyze them, thereby depositing silicon on the slim rods.

FIG. 1 schematically shows a cross-section of a reactor for growing high-purity polysilicon using the Siemens process described above.

Referring to FIG. 1, a reactor 30 includes a carbon chuck 60 that fixes to a slim rod or a silicon filament 40 and is connected to an electrode 20 that supplies a current received from a power source 10 to the carbon chuck 60. Usually, the silicon filament 40 is connected to two adjacent carbon chucks 60 in an inverted U-shape.

The carbon chuck 60 fixes the silicon filament 40 serving as a seed for the growth of the polysilicon 50, and also allows the current received through the electrode 20 connected thereunder to flow through the silicon filament 40, so that that the silicon filament 40 serving as a resistant substance can be heated.

After the silicon filament 40 is heated sufficiently, a reaction gas such as trichlorosilane and hydrogen gas are injected into the reactor 30. The reaction gas is pyrolyzed to be deposited on the silicon filament 40 in the form of polysilicon 50.

After the polysilicon 50 has been grown, the polysilicon 50 is acquired as it is deposited on the silicon filament 40 fixed at the top of the carbon chuck 60.

The carbon chuck 60 may remain in two forms shown in FIG. 2, respectively, after the polysilicon 50 has been collected.

FIG. 2 schematically show cross sections of the carbon chuck left after the polysilicon is obtained.

Referring to (a) in FIG. 2, a part of the silicon filament 40 is being inserted into a through hole 61 formed in the center of the upper end of the carbon chuck 60. In addition, a part of the polysilicon 50 may adhere to the upper end of the carbon chuck 60 and around the silicon filament 40.

Referring to (b) in FIG. 2, after the polysilicon adhering to the upper end of the carbon chuck 60 has been removed, a polysilicon fragment 51 may remain adhering only between the upper end and the lower end of the carbon chuck 60.

Previously, the polysilicon fragment 51 adhering to the carbon chuck 60 was separated and collected by using a physical method (for example, a blow using a hammer or the like) to thereby increase the gain of the polysilicon 50. In order to separate the polysilicon fragment 51 attached to the carbon chuck 60, a physical force is repeatedly applied. Accordingly, the carbon chuck 60 is damaged and thus it is difficult to reuse it.

To reuse the carbon chuck 60, there has been proposed an approach to chemically separate the polysilicon fragment 51 from the carbon chuck 60 by immersing the carbon chuck 60 with the polysilicon fragment 51 adhering thereto in a strong acid or strong base solution. Unfortunately, there are problems according to the approach in that the strong acid or strong base solution used for chemical separation is expensive, and that special attention is required for using such chemicals, which is troublesome. Further, the carbon chuck 60 or the polysilicon fragment 51 may be contaminated by the strong acid or strong base solution (or other additives contained therein), and thus an additional cleaning process is required, which is also troublesome.

Particularly, when the polysilicon fragment 51 adheres to only some portions of the carbon chuck 60 as shown in FIG. 2B, it is not possible to physically strike the carbon chuck 60, and thus the polysilicon fragment 51 has to be separated by chemically dissolving it.

### SUMMARY

It is an object of the present disclosure to provide a method for collecting polysilicon adhering to a carbon chuck and allowing for the carbon chuck to be reused, and an apparatus performing the method.

It is another object of the present disclosure to provide an apparatus and a method for separating polysilicon from a carbon chuck that can improve the gain of the polysilicon over existing methods for separating polysilicon from a carbon chuck by physical striking, and can prevent damage to the carbon chuck.

It is an object of the present disclosure to provide an apparatus and a method for separating polysilicon from a carbon chuck that can improve processing efficiency over existing chemical methods by reducing cost and process difficulty, and can prevent the carbon chuck and polysilicon from being contaminated by chemical components.

In accordance with one aspect of the present disclosure, an apparatus for separating polysilicon from a carbon chuck includes: a reactor comprising a holder for fixing a lower end of a carbon chuck, wherein a polysilicon adheres to an outer surface of the carbon chuck; and a heating coil disposed around an outer surface of the reactor such that it surrounds the polysilicon adhering to the carbon chuck, wherein the heating coil selectively heats the carbon chuck with a current induced by a high-frequency current applied from an external source.

A through hole may be formed at a center of the lower end of the carbon chuck, and an electrode for applying a current to the carbon chuck may be inserted into the insertion hole. The holder may be inserted into the through hole to fix the carbon chuck inside the reactor.

The polysilicon may adhere to a portion between an upper end and the lower end of the carbon chuck, and the holder may fix the lower end of the carbon chuck.

The carbon chuck may existing with no polysilicon adhering to the upper end and the lower end of the carbon chuck.

The carbon chuck may include a through hole where a silicon filament is inserted at the center of the upper end, and the carbon chuck may be held by the holder with the polysilicon adhering to the upper end of the carbon chuck and around the silicon filament.

The holder may hold the polysilicon adhering to the upper end of the carbon chuck and around the silicon filament or may hold the lower end of the carbon chuck where no polysilicon adheres.

The through hole of the carbon chuck may penetrate it so that the upper end is connected to the lower end of the carbon chuck. The apparatus may further include a gas injecting unit for injecting gas via the through hole from the lower end of the carbon chuck. When the contact surface between the polysilicon and the carbon chuck is melted by the induction-heating of the carbon chuck, the separation of the polysilicon can be facilitated.

The apparatus may further include a lower holder for holding polysilicon adhering to the upper end of the carbon chuck and around the silicon filament. Accordingly, when the contact surface is melted by the induction-heating of the carbon chuck, the lower holder may pull down the polysilicon in the falling direction of the polysilicon fragment, such that it is possible to further facilitate the separation of the polysilicon fragment.

The apparatus may further include a cooling unit for avoiding a part of the polysilicon that is not in contact with the carbon chuck from being melted when the carbon chuck is heated by the heating coil.

By maintaining the atmosphere temperature inside the reactor below a melting temperature of the polysilicon by the cooling unit, it is possible to avoid the rest part of the polysilicon not in contact with the carbon chuck from being melted and lost.

In accordance with another aspect of the present disclosure, a method for separating a polysilicon from a carbon chuck includes: fixing a lower end of a carbon chuck with polysilicon adhering to its outer surface to a holder; melting a contact surface between the carbon chuck and the polysilicon fragment by induction-heating by the carbon chuck; separating the polysilicon fragment from the carbon chuck as the contact surface is melted such that the polysilicon fragment free-falls by its own weight.

According to an exemplary embodiment of the present disclosure, by selectively melting the contact surface of the polysilicon fragment in contact with the carbon chuck, it is possible to reduce a damage to the carbon chuck and the polysilicon fragment and collect both of the carbon chuck and polysilicon fragment without damaging them.

According to an exemplary embodiment of the present disclosure, it is possible to separate polysilicon adhering to a carbon chuck without applying physical impact, and thus the intact carbon chuck can be reused immediately in a process of growing polysilicon.

In addition, it is not necessary to carrying out chemical process, and thus it is possible to prevent the carbon chuck and the polysilicon fragment from being contaminated by chemical components. Accordingly, unlike existing methods for chemically separating polysilicon from a carbon chuck, according to an exemplary embodiment of the present disclosure, no chemical cleaning process or no neutralizing process has to be carried out on the carbon chuck and polysilicon fragment, and thus processing efficiency can be improved.

### BRIEF DESCRIPTION OF DRAWINGS

FIG. 1 schematically shows a cross-section of a reactor for growing high-purity polysilicon using the Siemens process;

FIG. 2 schematically show cross sections of the carbon chuck left after the polysilicon is obtained;

FIG. 3 is a schematic cross-sectional view of an apparatus for separating polysilicon from a carbon chuck according to an exemplary embodiment of the present disclosure;

FIG. 4 is a cross-sectional view of an apparatus for separating polysilicon from a carbon chuck according to another exemplary embodiment of the present disclosure; and

FIGS. 5 to 10 illustrate separating polysilicon from a carbon chuck according to a variety of exemplary embodiments of the present disclosure.

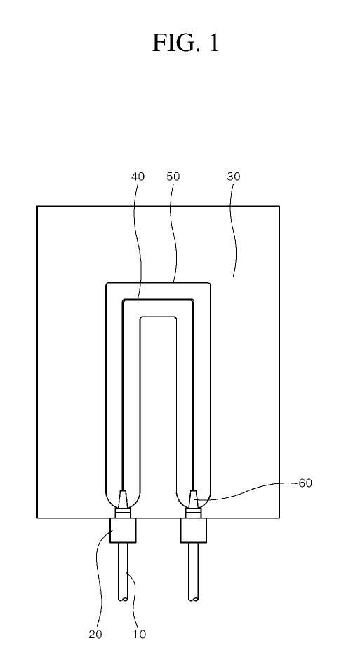

### DETAILED DESCRIPTION

Certain terms are defined herein for easy understanding. Unless specifically defined herein, scientific and technical terms used herein shall have the meanings commonly understood by those skilled in the art.

As used herein, the singular forms are intended to include plural forms and vice versa, unless the context clearly indicates otherwise.

Hereinafter, an apparatus and a method for separating polysilicon from a carbon chuck according to an exemplary embodiment of the present disclosure will be described in detail with reference to the drawings.

FIG. 3 is a schematic cross-sectional view of an apparatus for separating polysilicon from a carbon chuck according to an exemplary embodiment of the present disclosure.

Referring to FIG. 3, the apparatus 100 for separating polysilicon from a carbon chuck according to the exemplary embodiment of the present disclosure includes a batch reactor 110, a holder 120 disposed inside the reactor 110, and a heating coil 130 for inducing heating of the carbon chuck 60 fixed by the holder 120.

The reactor 110 may have a single jacket structure or a double jacket structure as desired. When the reactor 110 has a double jacket structure, the temperature inside the reactor 110 can be adjusted by circulating a cooling medium (for example, cooling water) by a cooling unit 150 in the space between the jackets.

In addition, the reactor 110 includes a gas supplying unit 140, and the gas atmosphere inside the reactor 110 may be determined by the gas supplied from the gas supplying unit 140. Typically, when the heating coil 130 heats the carbon chuck, the gas supplied by the gas supplying unit 140 is preferably an inert gas such as argon (Ar) to prevent contamination such as oxidation.

Shock-absorbing member 160 may be provided at the lower end of the reactor 110. When the polysilicon fragment is separated from the carbon chuck 60 by the induction-heating by the heating coil 130 and falls down, the shock-absorbing member 160 may have a predetermined thickness for reducing shock exerted on the polysilicon fragment when it collides with the lower end of the reactor 110.

In addition, the shock-absorbing member 160 may be made of chips, granules or a chunk of polysilicon, in order to prevent the polysilicon 50 from being contaminated.

The holder 120 is disposed inside the reactor 110, and fixes the carbon chuck to which the polysilicon fragment adheres.

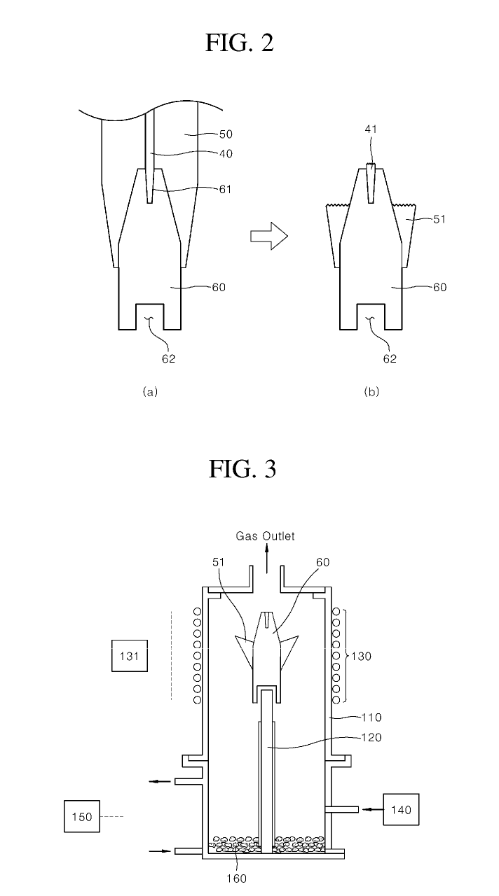

The apparatus shown in FIG. 3 is especially useful to collect the polysilicon fragment 51 from the carbon chuck after the polysilicon fragment is partially removed from the upper end of the carbon chuck 60 and the polysilicon fragment remains only some portion between the upper end and lower end of the carbon chuck 60, as shown in FIG. 2.

Accordingly, the holder 120 is inserted into an electrode insertion portion 62 formed at the lower end of the carbon chuck and fixed in the reactor 110, with the polysilicon fragment 51 adhering to some portions between the upper end and the lower end of the carbon chuck 60.

The heating coil 130 is wound around the reactor 110 at the location where it surrounds the contact surface between the polysilicon fragment 51 the carbon chuck 60, with the carbon chuck 60 having the polysilicon fragment 51 adhering thereto being fixed to the holder 120. For example, the heating coil 130 may be disposed at the same level as the polysilicon fragment 51 forming the contact surface with the carbon chuck 60.

The heating coil 130 is a heating means for causing induction-heating of the carbon chuck 60. By induction-heating the carbon chuck 60, the contact surface between the carbon chuck 60 and the polysilicon fragment 51 is melted, so that the carbon chuck 60 and the polysilicon fragment 51 are separated from each other.

To this end, a high-frequency current is applied to the heating coil 130 by a current supplying unit 131, such that an induced current is generated by the applied high-frequency current. An induced current is generated also in the carbon chuck 60 by the electromagnetic induction caused by the induced current generated by the heating coil 130. A resistance heat is generated by the induced current loss and the hysteresis loss due to the resistance characteristic of the carbon chuck 60 itself.

The frequency of the current flowing to the heating coil 130 for melting the contact surface between the polysilicon fragment 51 and the carbon chuck 60 is preferably 1 kHz to 500 kHz, more preferably 1 kHz to 100 kHz.

If the frequency of the current flowing to the heating coil 130 is less than 1 kHz, the effect of induction-heating on the carbon chuck 60 is too small, and thus it may take too long to heat the carbon chuck 60 up to a predetermined temperature (i.e., the temperature sufficient to cause melting of the contact surface between the polysilicon section 51 and the carbon chuck 60) or it may fail to reach the temperature to cause melting of the contact surface of the polysilicon fragment 51.

On the contrary, if the frequency of the current flowing to the heating coil 130 is higher than 500 kHz, the induction-heating may take place also in the polysilicon fragment 51 in addition to the carbon chuck 60. As a result, even the polysilicon fragment 51 may be melted as well as the contact surface between the polysilicon fragment 51 and the carbon chuck 60. When this happens, it is difficult to obtain the polysilicon fragment 51 without as desired, and the polysilicon fragment 51 may be contaminated during the process of once melting it and then solidifying it again.

Additionally, the cooling unit 150 disposed in the apparatus can avoid the part of polysilicon fragment 51 not in contact with the carbon chuck 60 from being melted when the carbon chuck 60 is induction-heated by the heating coil 130.

By maintaining the atmosphere temperature inside the reactor 110 below a melting temperature of the polysilicon fragment 51, typically below 1,000 □ by the cooling unit 150, it is possible to avoid the rest part of the polysilicon fragment 51 not in contact with the carbon chuck 60 from being melted.

In addition, after the polysilicon fragment 51 has been separated from the carbon chuck 60, the heating coil 130 disposed in the apparatus according to an exemplary embodiment of the present disclosure may remove the residuals of the polysilicon fragment 51 remaining on the outer surface of the carbon chuck 60 by second induction-heating.

To this end, the current supplying unit 131 may apply a current having a frequency of 500 kHz to 3 MHz to the heating coil 130, to melt the residuals of the polysilicon fragment 51 by induction-heating of the carbon chuck 60 or to remove the residuals of the polysilicon fragment 51 remaining on the outer surface of the carbon chuck 60 by heating the polysilicon fragment 51.

For example, some of the polysilicon fragment 51 adhering to the outer surface of the carbon chuck 60 may be removed by the first induction-heating, and then residuals of the polysilicon fragment 51 remaining on the outer surface of the carbon chuck 60 may be removed by the second induction-heating.

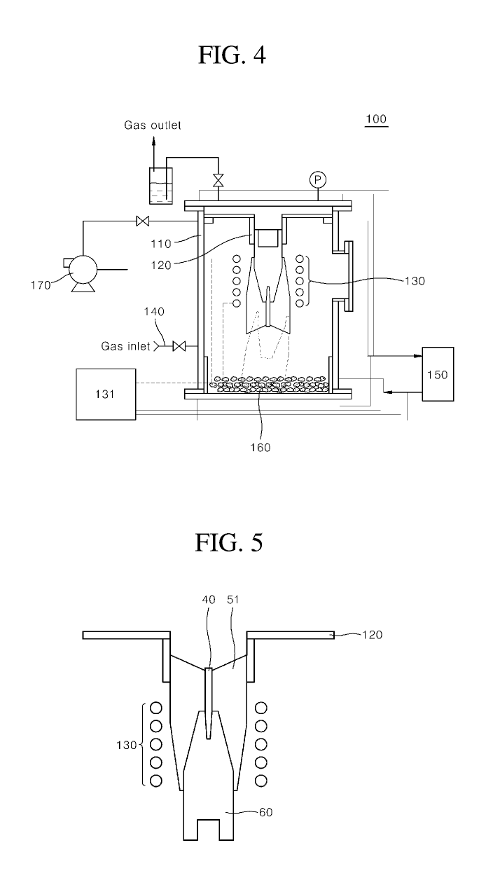

FIG. 4 is a cross-sectional view of an apparatus for separating polysilicon from a carbon chuck according to another exemplary embodiment of the present disclosure.

Referring to FIG. 4, the apparatus 100 for separating polysilicon from a carbon chuck according to this exemplary embodiment of the present disclosure includes a batch reactor 110, a holder 120 disposed inside the reactor 110, and a heating coil 130 for inducing heating of the carbon chuck 60 held by the holder 120.

The reactor 110 may have a single jacket structure or a double jacket structure as desired. When the reactor 110 has a double jacket structure, the temperature inside the reactor 110 can be adjusted by circulating a cooling medium (for example, cooling water) by a cooling unit 150 in the space between the jackets.

In addition, a vacuum atmosphere (positive pressure or negative pressure) may be created inside the reactor 110 by a vacuum pump 170 or the like. Accordingly, it is possible to prevent contamination such as oxidation during heating by the heating coil 130.

In addition, the reactor 110 includes a gas supplying unit 140, and the gas atmosphere inside the reactor 110 may be determined by the gas supplied from the gas supplying unit 140. Typically, when the heating coil 130 heats the carbon chuck, the gas supplied by the gas supply unit 140 is preferably an inert gas to prevent contamination such as oxidation.

Shock-absorbing material 160 may be provided at the lower end of the reactor 110. When the polysilicon fragment 51 is separated from the carbon chuck 60 by the induction-heating by the heating coil 130 and falls down, the shock-absorbing material 160 may have a predetermined thickness for reducing shock exerted on the polysilicon fragment 51 when it collides with the lower end of the reactor 110.

In addition, the shock-absorbing member 160 may be made of chips, granules or a chunk of polysilicon, in order to prevent the polysilicon fragment 51 from being contaminated.

The holder 120 is disposed inside the reactor 110, and fixes the carbon chuck to which the polysilicon adheres.

The apparatus shown in FIG. 4 may be especially useful to collect the polysilicon fragment 51 from the carbon chuck 60 after obtaining the polysilicon 50 that has been grown using the silicon filament 40 inserted into the through hole 61 formed at the upper center portion of the carbon chuck 60, as shown in (a) in FIG. 2. In addition, the apparatus may be useful to collect the polysilicon fragment 51 from the carbon chuck 60 to some portion of which residuals of the polysilicon fragment 51 adhere, as well as around the silicon filament 40 inserted into the carbon chuck 60.

Accordingly, the polysilicon fragment 51 is disposed in and fixed to the upper end of the reactor 110 by the holder 120 while adhering to the upper end of the carbon chuck 60 and around the silicon filament 40.

The heating coil 130 is disposed at the location where it surrounds the contact surface between the polysilicon fragment 51 the carbon chuck 60, with the carbon chuck 60 having the polysilicon fragment 51 adhering thereto being held by the holder 120. For example, the heating coil 130 may be disposed at the same level as the polysilicon fragment 51 forming the contact surface with the carbon chuck 60.

The heating coil 130 is a heating means for causing induction-heating of the carbon chuck 60. By induction-heating the carbon chuck 60, the contact surface between the carbon chuck 60 and the polysilicon fragment 51 is melted, so that the carbon chuck 60 and the polysilicon fragment 51 are separated from each other.

To this end, a high-frequency current is applied to the heating coil 130 by a current supplying unit 131, such that an induced current is generated by the applied high-frequency current. An induced current is generated also in the carbon chuck 60 by the electromagnetic induction caused by the induced current generated by the heating coil 130. A resistance heat is generated by the induced current loss and the hysteresis loss due to the resistance characteristic of the carbon chuck 60 itself.

The frequency of the current flowing to the heating coil 130 for melting the contact surface between the polysilicon fragment 51 and the carbon chuck 60 is preferably 1 kHz to 500 kHz, more preferably 1 kHz to 100 kHz.

If the frequency of the current flowing to the heating coil 130 is less than 1 kHz, the effect of induction-heating on the carbon chuck 60 is too small, and thus it may take too long to heat the carbon chuck 60 up to a predetermined temperature (i.e., the temperature sufficient to cause melting of the contact surface between the polysilicon section 51 and the carbon chuck 60) or it may fail to reach the temperature to cause melting of the contact surface of the polysilicon fragment 51.

On the contrary, if the frequency of the current flowing to the heating coil 130 is higher than 500 kHz, the induction-heating may take place also in the polysilicon fragment 51 in addition to the carbon chuck 60. As a result, even the polysilicon fragment 51 may be melted as well as the contact surface between the polysilicon fragment 51 and the carbon chuck 60. When this happens, it is difficult to obtain the polysilicon fragment 51 without as desired, and the polysilicon fragment 51 may be contaminated during the process of once melting it and then solidifying it again.

FIGS. 5 to 10 illustrate separating polysilicon from a carbon chuck using the apparatus shown in FIG. 4 according to a variety of exemplary embodiments of the present disclosure.

Referring to FIG. 5, the holder 120 holds the upper end of the polysilicon fragment 51 adhering around the upper end of the carbon chuck 60 and the silicon filament 40 inserted into the carbon chuck 60.

When the carbon chuck 60 is heated by the electromagnetic induction generated as a high-frequency current is applied to the heating coil 130, the temperature of the carbon chuck 60 increases to the temperature higher than the melting point of the polysilicon, and thus the contact surface between the polysilicon section 51 and the carbon chuck 60 is melted.

Since the upper end of the polysilicon fragment 51 is fixed by the holder 120, when the carbon chuck 60 and the polysilicon fragment 51 are separated from each other, the carbon chuck 60 falls on the bottom of the reactor 110 on its own weight.

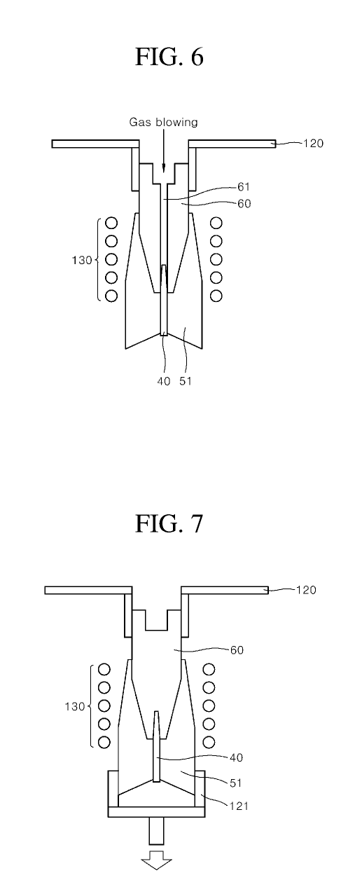

Referring to FIG. 6, the holder 120 holds the lower end of the carbon chuck 60 where no polysilicon fragment adheres. It is to be noted that the through hole 61 for inserting the silicon filament 40 into the carbon chuck 60 used in the example shown in FIG. 6 penetrates the carbon chuck so that the upper end is connected to the lower end of the carbon chuck 60.

In this exemplary embodiment, the apparatus according to an exemplary embodiment of the present disclosure may further include a gas injecting unit for injecting gas (an inert gas such as argon (Ar)) through the through hole 61 from the lower end of the carbon chuck 60. By blowing the gas through the through hole 61 when the contact surface between the polysilicon section 51 and the carbon chuck 60 is melted by the electromagnetic induction of the heating coil 130, it is possible to further facilitate the separation of the polysilicon fragment from the carbon chuck 60.

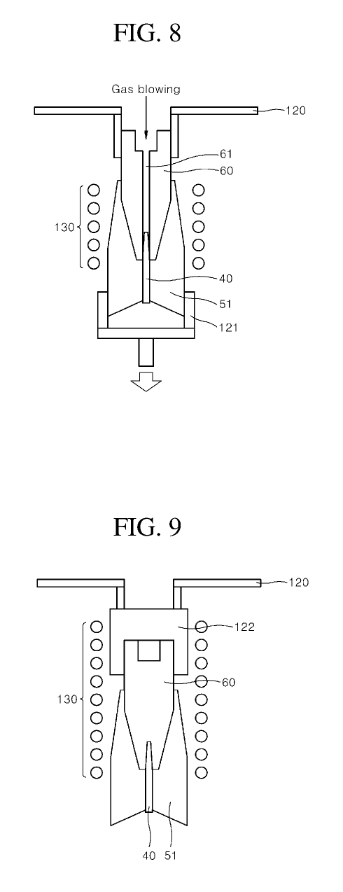

Referring to FIGS. 7 and 8, an apparatus for separating according to an exemplary embodiment of the present disclosure includes a holder 120 for holding a lower end of a carbon chuck 60 where no polysilicon fragment adheres, and a lower holder 121 for holding a polysilicon fragment 51 adheres to the upper end of the carbon chuck 60 and around the silicon filament 40.

Accordingly, when the carbon chuck 60 is induction-heated by the heating coil 130, the lower holder 121 pulls down the polysilicon fragment 51 it holds in the falling direction of the polysilicon fragment 51, such that it is possible to further facilitate the separation of the polysilicon fragment 51 from the carbon chuck 60.

In doing so, when the carbon chuck 60 having the through hole 61 penetrating it in the vertical direction is used, the gas is blown through the through-hole 61, so that it is possible to reduce the time taken for separating the polysilicon fragment 51 from the carbon chuck 60, as shown in FIG. 8.

Referring to FIG. 9, an apparatus for separating polysilicon from a carbon chuck according to an exemplary embodiment of the present disclosure may further include an auxiliary heating block 122. The auxiliary heating block 122 may be provided at the holder 120, and the lower end of the carbon chuck 60 where no polysilicon fragment adheres may be held by the auxiliary heating block 122.

For example, if the carbon chuck 60 is too small to be held by the holder 120 or the shape of the lower end of the carbon chuck 60 held by the holder 120 is irregular, the carbon chuck 60 may be held via the auxiliary heating block 122, so that the carbon chuck 60 can be stably fixed to the holder 120 while being heated by induction-heating.

Further, the auxiliary heating block 122 is also a heating means for heating the carbon chuck 60. By heating the carbon chuck 60 by the auxiliary heating block 122 along with the heating coil 130, it is possible to reduce the time taken until the carbon chuck 60 is heated to a predetermined temperature (i.e., a temperature sufficient to melt the contact surface between the polysilicon fragment 51 and the carbon chuck 60).

Since the auxiliary heating block 122 comes in contact with the carbon chuck 60 and directly heats it, the polysilicon fragment 51 is not directly heated by the auxiliary heating block 122. Accordingly, it is possible to avoid the other portion of the polysilicon fragment 51 than the contact surface with the carbon chuck 60 from being heated by heating means or the like.

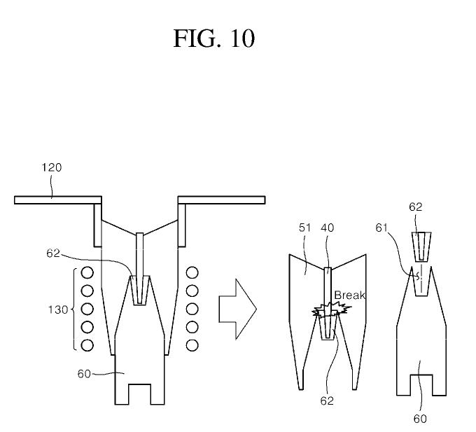

Referring to FIG. 10, the holder 120 holds the upper end of the polysilicon fragment 51 adhering around the upper end of the carbon chuck 60 and the silicon filament 40 inserted into the carbon chuck 60, wherein in a through hole 61 of the carbon chuck 61 used in the example shown in FIG. 10, an auxiliary insertion portion 64 is disposed where a silicon filament 40 is inserted, instead of the silicon filament being directly inserted into the through hole 61. Accordingly, the auxiliary insertion portion 62 where the silicon filament 40 is inserted is inserted into the through hole 61 of the carbon chuck 60.

Sometimes, the polysilicon fragment 51 is not easily separated from the carbon chuck 60 by induction-heating due to the silicon filament 40 inserted into the through hole 61 of the carbon chuck 60. To overcome this, by increasing the temperature that the carbon chuck 60 reaches by the induction-heating to thereby increase the melting point of the polysilicon fragment 51, it is possible to easily separate the polysilicon fragment 51 from the carbon chuck 60. However, this may cause a problem that the polysilicon fragment 51 is lost by the melting.

In view of the above, according to the exemplary embodiment of the present disclosure, the silicon filament 40 is inserted into the auxiliary insertion portion 62 and then is inserted into the through hole 61 of the carbon chuck 60, and the auxiliary insertion portion 62 can be separated from the carbon chuck 60 together with the silicon filament 40. By doing so, it is possible to address the problem that the silicon filament 40 is firmly fixed to the carbon chuck 60 and is not separated.

Then, by using a new auxiliary insertion portion 62 for the carbon chuck 60 after the polysilicon fragment 51 is separated therefrom, it is possible to reuse the carbon chuck 60 that remains intact.

Additionally, the cooling unit 150 disposed in the apparatus can avoid the part of polysilicon fragment 51 not in contact with the carbon chuck 60 from being melted when the carbon chuck 60 is induction-heated by the heating coil 130.

By maintaining the atmosphere temperature inside the reactor 110 below a melting temperature of the polysilicon fragment 51, typically below 1,000 □ by the reactor 150, it is possible to avoid the rest part of the polysilicon fragment 51 not in contact with the carbon chuck 60 from being melted.

In addition, after the polysilicon fragment 51 has been separated from the carbon chuck 60, the heating coil 130 disposed in the apparatus according to an exemplary embodiment of the present disclosure may remove the residuals of the polysilicon fragment 51 remaining on the outer surface of the carbon chuck 60 by second induction-heating.

To this end, the current supplying unit 131 may apply a current having a frequency of 500 kHz to 3 MHz to the heating coil 130, to melt the residuals of the polysilicon 50 by induction-heating of the carbon chuck 60 or to remove the residuals of the polysilicon fragment 51 remaining on the outer surface of the carbon chuck 60 by heating the polysilicon fragment 51.

Although the present disclosure has been described with reference to exemplary embodiments thereof, the present disclosure is not limited thereby. Indeed, the exemplary embodiments are provided for illustrative and non-limitative purposes. Changes, modifications, enhancements and/or refinements thereto may be made without departing from the spirit or scope of the present disclosure. Accordingly, such changes, modifications, enhancements and/or refinements are encompassed within the scope of the present disclosure.

What is claimed is:

1. An apparatus for separating polysilicon from a carbon chuck, the apparatus comprising:
a reactor comprising a holder for fixing a lower end of a carbon chuck, wherein a polysilicon fragment adheres to an outer surface of the carbon chuck; and
a heating coil disposed around an outer surface of the reactor such that it surrounds the polysilicon fragment adhering to the carbon chuck,
wherein the heating coil selectively heats the carbon chuck with a current induced by a high-frequency current applied from an external source.

2. The apparatus of claim 1, wherein a through hole is formed at a center of the lower end of the carbon chuck, wherein an electrode for applying a current to the carbon chuck is inserted into the insertion hole, and
wherein the holder is inserted into the through hole to fix the carbon chuck inside the reactor.

3. The apparatus of claim 2, wherein the holder fixes the lower end of the carbon chuck with the polysilicon fragment adhering to a portion between an upper end and the lower end of the carbon chuck.

4. The apparatus of claim 3, wherein the carbon chuck is fixed by the holder with no polysilicon fragment adhering to the upper end and the lower end of the carbon chuck.

5. The apparatus of claim 1, wherein a current having a frequency of 500 kHz or less is applied to the heating coil to selectively induction-heat the carbon chuck.

6. The apparatus of claim 1, wherein the holder further comprises an auxiliary heating block for heating the lower end of the carbon chuck.

7. The apparatus of claim 1, further comprising: a cooling unit, wherein the cooling unit cools down a portion of the polysilicon fragment that is not in contact with the carbon chuck while the carbon chuck is heated by the heating coil.

8. A method for separating a polysilicon fragment adhering to an outer surface of a carbon chuck, the method comprising:
fixing a lower end of a carbon chuck to a holder, a polysilicon fragment adhering to an outer surface of the carbon chuck;
melting a contact surface between the carbon chuck and the polysilicon fragment by induction-heating by the carbon chuck; and
separating the polysilicon fragment from the carbon chuck as the contact surface is melted such that the polysilicon fragment free-falls by its own weight.

9. The method of claim 8, wherein the contact surface between the carbon chuck and the polysilicon fragment is melted by heat transferred from the carbon chuck that has been induction-heated.

10. The method of claim 8, wherein a frequency of a current applied to induction-heat the carbon chuck is equal to or less than 500 kHz.

11. The method of 8, further comprising: after separating a part of the polysilicon fragment adhering to the outer surface of the carbon chuck, applying a current having a frequency of 500 kHz to 3 MHz to the carbon chuck to thereby remove residuals of the polysilicon fragment remaining on the outer surface of the carbon chuck.
